(19) United States
(12) Patent Application Publication
(10) Pub. No.: US 2008/0292878 A1
(43) Pub. Date: Nov. 27, 2008

(54) POLYIMIDE FILM WITH IMPROVED ADHESION, PROCESS FOR ITS FABRICATION AND LAMINATED BODY

(75) Inventors: Takashi Kino, Ichihara-shi (JP); Masafumi Kohda, Ichihara-shi (JP); Masato Murakami, Ichihara-shi (JP); Hiroaki Yamaguchi, Ichihara-shi (JP)

Correspondence Address: IP GROUP OF DLA PIPER US LLP, ONE LIBERTY PLACE, 1650 MARKET ST, SUITE 4900, PHILADELPHIA, PA, 19103, US

(73) Assignee: Ube Industries, Ltd.,, Ube-shi (JP)

(21) Appl. No.: 12/164,203

(22) Filed: Jun. 30, 2008

Related U.S. Application Data
(62) Division of application No. 11/216,748, filed on Aug. 31, 2005.

(30) Foreign Application Priority Data
Dec. 27, 2004 (JP) JP 2004-375581

(51) Int. Cl. B32B 15/08; C23C 16/00; C23C 14/34

(52) U.S. Cl. 428/336; 428/458; 428/337; 427/255.394; 204/192.15

(57) ABSTRACT

A laminated body obtained by forming a metal-deposited layer onto one or both adhesion-improved sides of a polyimide film with improved adhesion obtained by coating and spraying an organic polar solvent solution containing a polybenzimidazole onto one or both sides of a self-supporting film prepared by casting and drying a dope, which is an organic polar solvent solution of a polyimide precursor which may contain an imidization catalyst, onto a support and then heat treating the film to form a multilayer polyimide film of a base polyimide layer and one or two polybenzimidazole layers, by vapor deposition or sputtering, and then plating with metal to form a metal layer onto the metal-deposited layer.

### RELATED APPLICATION

This application is a divisional of U.S. application Ser. No. 11/216,748, filed Aug. 31, 2005, which claims priority of Japanese Patent Application No. 2004-375581, filed Dec. 27, 2004, herein incorporated by reference.

### TECHNICAL FIELD

This disclosure relates to a polyimide film exhibiting improved adhesion to the film surface essentially without impairment of the mechanical properties, thermal properties and electrical/electronic properties of the polyimide film, as well as to a process for its fabrication and to a laminated body employing it.

### BACKGROUND

Polyimide films have excellent thermal properties and electrical properties and are therefore widely employed for various purposes in electronic devices. However, polyimide films do not exhibit high adhesive strength with the adhesives that are ordinarily used in the field of electronics, and cannot yield laminated bodies with high peel strengths even when metal layers are formed by metal vapor deposition or sputtering.

Numerous attempts have been made to improve the adhesion of polyimide films. For example, polyimide films with improved adhesion comprising 0.02-1 wt % of tin, bismuth or antimony compounds have been reported (Japanese Unexamined Patent Publication No. 4-261466, Japanese Unexamined Patent Publication No. 6-073209, Japanese Unexamined Patent Domestic Publication No. 7-503984). However, such polyimide films potentially exhibit reduced electrical properties such as electrical insulation.

Also reported have been techniques for improving the adhesion of polyimide films by plasma discharge treatment (Japanese Unexamined Patent Publication No. 59-86634, Japanese Unexamined Patent Publication No. 2-134241). However, discharge treatment often has an insufficient effect of improving the polyimide film adhesion, and productivity is low because of the requirement for complex post-treatment steps.

It could therefore be advantageous to provide a polyimide film with satisfactory adhesion, sputtering properties and metal vapor deposition properties while maintaining the excellent characteristics typical of aromatic polyimide films including thermal properties, physical properties and electrical properties, as well as a process for its fabrication and a laminated body thereof.

### SUMMARY

We provide a polyimide film with improved adhesion obtained by coating or spraying an organic polar solvent solution containing a polybenzimidazole onto one or both sides of a self-supporting film prepared by casting and drying a dope which is an organic polar solvent solution of a polyimide precursor which may contain an imidization catalyst, onto a support and then thoroughly heat treating the film.

We further provide a process for the fabrication of a polyimide film with improved adhesion whereby an organic polar solvent solution containing a polybenzimidazole is coated or sprayed onto one or both sides of a self-supporting film prepared by casting and drying a dope, which is an organic polar solvent, solution of a polyimide precursor which may contain ah imidization catalyst, onto a support, and the film is then thoroughly heat treated.

We still further provide a cover lay film prepared by laminating a cover lay film adhesive on the aforementioned polyimide film with improved adhesion.

We still further provide a laminated body obtained by laminating a metal foil, via a heat-resistant adhesive, onto one or both adhesion-improved sides of the aforementioned polyimide film with improved adhesion, or to a laminated body obtained by forming a metal thin-layer onto one or both adhesion-improved sides of the aforementioned polyimide film with improved adhesion by vapor deposition or sputtering, and then plating with metal to form a metal layer.

The polyimide film with improved adhesion has satisfactory adhesion, sputtering properties and metal vapor deposition properties while maintaining the characteristics of an aromatic polyimide film. In addition, the process can produce polyimide films with satisfactory adhesion, sputtering properties and metal vapor deposition properties by a simple procedure, while maintaining the characteristics of the base aromatic polyimide film.

The laminated body comprises a base polyimide film and metal layer laminated together by a strong adhesive force.

### DETAILED DESCRIPTION

Preferred modes will now be described.

The base polyimide is preferably produced from 3,3′,4,4′-biphenyltetracarboxylic dianhydride (hereinafter also abbreviated as s-BPDA) and para-phenylenediamine (hereinafter also abbreviated as PPD), and optionally 4,4′-diaminodiphenylether (hereinafter also abbreviated as DADE). In this case, the PPD/DADE (molar) ratio is preferably between 100/0 and 85/15.

The base polyimide may also be produced from 3,3′,4,4′-biphenyltetracarboxylic dianhydride, pyromellitic dianhydride, para-phenylenediamine and 4,4′-diaminodiphenylether. In this case, the BPDA/PMDA ratio is preferably between 15/85 and 85/15 and the PPD/DADE ratio is preferably between 90/10 and 10/90.

The base polyimide may also be produced from pyromellitic dianhydride, para-phen-ylenediamine and 4,4′-diaminodiphenylether. In this case, the DADE/PPD ratio is preferably between 90/10 and 10/90.

The base polyimide may also be produced from 3,3′,4,4′-benzophenonetetracarboxylic dianhydride (BTDA), pyromellitic dianhydride, para-phenylenediamine and 4,4′-diaminodiphenylether. In this case, the BTDA/PMDA ratio in the acid dianhydride is preferably between 20/80 and 90/10, and the PPD/DADE ratio in the diamine is preferably between 30/70 and 90/10.

The base polyimide may be synthesized by any method, including random polymerization or block polymerization of the aforementioned aromatic tetracarboxylic dianhydride and aromatic diamine in an organic solvent in approximately equimolar amounts, or by first synthesizing two or more polyamic acids with one of the components, in excess and mixing the polyamic acid solutions under reaction conditions.

A surface-modifying polybenzimidazole is produced from an aromatic tetraamine and an aromatic dicarboxylic acid.

As examples of aromatic tetraamines there may be mentioned 3,3′,4,4′-tetraaminobiphenyl; 1,2,4,5-tetraaminobenzene; 1,2,5,6-tetraaminonaphthalene; 2,3,6,7-tefraaminonaphthalene; 3,3′,4,4′-tetraaminodiphenylmethane; sym-3,3′,4,4′-tetraaminodiphenylethane; 3,3′,4,4′-tetraaminodiphenyl-2,2-propane; 2,2-tetraaminodiphenylsulfide; and 3,3′,4,4′-tetraaminodiphenylsulfone. A preferred aromatic tetraamine is 3,3′,4,4′-tetraaminobiphenyl.

As examples of aromatic dicarboxylic acids there may be mentioned isophthalic acid; terephthalic acid; 4,4′-biphenyldicarboxylic acid; 1,4-naphthalenedicarboxylic acid; 2,2′-biphenyldicarboxylic acid (diphenic acid); phenylindanedicarboxylic acid; 1,6-naphthalenedicarboxylic acid; 2,6-naphthalenedicarboxylic acid; 4,4′-diphenyletherdicarboxylic acid; 4,4′-diphenylsulfonedicarboxylic acid; and 4,4′-diphenylthioethercarboxylic acid. Isophthalic acid (IPA) is the most preferred dicarboxylic acid.

A multilayer polyimide film as a polyimide film with improved adhesion is preferably produced, during lamination of the surface-modifying polybenzimidazole on the base polyimide film, by thinly coating a coating solution comprising an organic solvent solution which contains a surface-modifying polybenzimidazole onto at least a portion of a self-supporting molded sheet serving as the precursor for the base polyimide fi lm, and then thoroughly heat treating the film.

According to this method, the self-supporting film serving as the base polyimide film may be produced by adding an imidization catalyst to an organic solvent solution of a polyamic acid which yields the aforementioned base polyimide, and then casting and coating it onto a support (for example, a glass panel, stainless steel sheet, stainless steel belt or the like) and heating to a degree which causes it to exhibit a self-supporting property (usually a stage prior to the curing stage), such as, for example, to 100-180° C. for about 5-60 minutes. The polyamic acid solution for the base polyimide preferably has a polymer concentration of about 8-25 wt %. An organic phosphorus compound or necessary amounts of inorganic fine powdered filler materials may also be added to the polyamic acid solution.

As imidization catalysts there may be mentioned substituted or unsubstituted nitrogen-containing heterocyclic compounds, N-oxides of such nitrogen-containing heterocyclic compounds, substituted or unsubstituted amino acid compounds, and aromatic hydrocarbon compounds or aromatic heterocyclic compounds with hydroxyl groups, and particularly preferred for use are lower alkylimidazoles such as 1,2-dimethylimidazole, N-methylimidazole, N-benzyl-2-methylimidazole, 2-methylimidazole, 2-ethyl-4-imidazole and 5-methylbenzimidazole, benzimidazoles such as N-benzyl-2-methylimidazole, and substituted pyridines such as isoquinoline, 3,5-dimethylpyridine, 3,4-dimethylpyridine, 2,5-dimethylpyridine, 2,4-dimethylpyridine and 4-n-propylpyridine. The amount of imidization catalyst used is preferably 0.01-2 equivalents and especially about 0.02-1 equivalent with respect to the amide acid unit of the polyamic acid. Using such an imidization catalyst is preferred to improve the physical properties, and especially the elongation and end checking resistance, of the obtained polyimide film.

In the process described above, the coating solution (or spraying solution) containing the surface-modifying polybenzimidazole must be applied at the stage of the self-supporting molded sheet which is to serve as the precursor for the base polyimide film, preferably to a thickness of about 0.01 -3.0 μm as a dry film, and then subjected it to heat treatment for drying and oxidation.

The coating solution or spraying solution containing the surface-modifying polybenzimidazole preferably has a polymer concentration of about 0.1-10 wt % in the organic solvent solution. Publicly known additives, such as necessary amounts of inorganic fine particle fillers, may also be added to the coating solution. The types and amounts of such additives may be appropriately selected depending on the purpose. The coating solution is thinly applied or sprayed, preferably to a polybenzimidazole layer thickness of 0.01-3.0 μm, by dip coating, screen printing, curtain coating, roll coating, gravure coating, die coating, spraying or the like, and then heat treated for drying and oxidation.

As organic solvents for the base polyimide precursor and surface-modifying polybenzimidazole there may be mentioned N-methyl-2-pyrrolidone, N,N′-dimethylformamide, N,N′-dimethylacetamide and N,N-diethylacetamide. These organic solvents may be used along or in combinations of two or more. The organic solvent for production of the base polyimide precursor and the organic solvent for the surface-modifying polybenzimidazole may be either the same or different solvents.

The heat treatment in the process described above is preferably heat treatment by heating at a temperature above the glass transition temperature of the crystalline polyimide and no higher than 500° C., and especially to 350-500° C. as the maximum temperature. Particularly preferred is multistage heating at 100-250° C. for about 1-30 minutes, followed by heating at 400-500° C. for about 0.5-30 minutes.

This process can yield a multilayer polyimide film integrating a base polyimide layer and a surface-modifying polybenzimidazole thin-layer. The surface-modifying polybenzimidazole single film used for this process (a film formed from PBI MRS0810H by Clariant, Japan) has a Tg of 430° C. and a thermal decomposition temperature of 580° C. (5% weight reduction temperature), and is therefore completely satisfactory in terms of heat resistance. Consequently, a polyimide film with improved adhesion according to the invention has vastly improved adhesion with virtually no impairment of the base polyimide characteristics. In particular, when the base polyimide layer thickness is 10-100 μm and the surface-modifying polybenzimidazole layer thickness is 0.01-3.0 μm, the multilayer polyimide film has a tensile strength of 30-100 kg/mm², an elastic modulus of 600-1200 kg/mm², an elongation of 30-100%, a water absorption (after 24 hours immersed in water at 23° C.) of no greater than 1.5% and a thermal expansion coefficient (23-300° C., both TD and MD) of 0.5-2.5×10⁻⁵ cm/cm/° C.

Thus, the polyimide film with improved adhesion may be suitably used as a base film such as a laminated metal clad base or sputtered metal clad base, or as the base film of a metal vapor deposited film. The process applied for fabrication of the metal foil laminate may be a publicly known process, such as a process described in “Handbook of Printed Circuit Techniques” (Nikkan Kogyo Shimbun, 1993).

As metal thin-films with at least two layers, there may be mentioned bilayer metal vapor deposition layers preferably comprising a lower metal vapor deposition layer and a copper vapor deposition layer formed thereover. An electroplated layer may also be formed over this bilayer metal thin-film. As a metal thin-film with at least two layers, there may be mentioned a bilayer metal layer comprising electroless plating and electroplating.

The process for vapor deposition of a metal to form a metal layer by metal vapor deposition or metal vapor deposition and metal plating may be a vapor deposition method such as vacuum vapor deposition or sputtering. For vacuum vapor deposition, the vacuum degree is preferably about 10⁻⁵ to 1 Pa and the vapor deposition speed is preferably about 5-500 nm/sec. For sputtering, DC magnetosputtering is particularly preferred, with a vacuum degree of preferably no greater than 13 Pa and especially about 0.1-1 Pa, and a layer formation speed of about 0.05-50 nm/sec. The thickness of the obtained metal vapor deposition film is between 10 nm and 1 μm, with 0.1-0.5 μm being preferred. It is also preferred to form a thick film by metal plating thereover. The thickness of such a film is about 1-20 μm.

Various combinations may be used as the material for the metal thin-film. The metal vapor deposition film may have a structure with two or more layers, comprising as the metal vapor deposition film an underlying layer and a surface vapor deposited metal layer. The underlying layer may be at least one from among chromium, titanium, palladium, zinc, molybdenum, nickel, cobalt, zirconium, iron and the like. Copper may be mentioned as the surface layer (or interlayer). The material for the metal plating layer formed on the vapor deposition layer is preferably copper, copper alloy, silver or the like, and especially copper. The method of forming the metal plating layer may be an electro less plating or electroplating method. Also, an underlying metal layer of a metal such as chromium,, titanium, palladium, zinc, tin, molybdenum, nickel, cobalt, zirconium, iron or the like, or an alloy thereof such as nickel-copper or nickel-chromium alloy may be formed on one side of a vacuum plasma discharge treated polyimide film, a vapor deposition layer of copper formed thereover as an interlayer, and then a copper electroless plating layer formed (formation of an electroless plating layer is effective for filling in generated pinholes), or the thickness of the metal vapor deposition layer may be increased to, for example, 0.1-1.0 μm, and the copper or other electroless metal plating layer omitted to form an electroplated copper layer as the surface layer.

Our films and processes will now be explained in greater detail using Examples and Comparative Examples.

### EXAMPLE 1

A polyimide starting material dope (prepared by adding 1,2-dimethylimidazole at 0.05 equivalent with respect to polyamic acid to a solution obtained under the conditions: 3,3′,4,4′-biphenyltetracarboxylic dianhydride/p-phenylenediamine, 18 wt % polyamic acid concentration, organic solvent: dimethylacetamide) was cast and coated onto a stainless steel base and dried at 135° C. for 12 minutes, and then peeled from the stainless steel base to obtain a self-supporting film with a solvent content of 30-35 wt %. A surface-modifying polybenzimidazole solution (PBI MRS0810H by Clariant, Japan) diluted to 2 wt % was coated onto the film at a coverage of 10 g/m², and then heat treated at 180° C. for 1 minute, 320° C. for 3 minutes and 450° C. for 3 minutes, to fabricate a bilayer polyimide film (total thickness: 12.5 μm) having the surface covered (laminated) with a polybenzimidazole layer (approximately 0.2 μm). The bilayer polyimide film had improved surface adhesion, as demonstrated below, while maintaining a low linear expansion coefficient, high elastic modulus and high strength as characteristics of the base polyimide film.

### Fabrication of Copper Foil Laminate Film Using Adhesive

An acrylic adhesive (PYRALUX LF-0100 by DuPont K.K., 25 μm thickness) was placed over a rolled copper foil (BHY-13H-T by Nikko Materials K.K., 18 μm thickness), and the modified side of the bilayer film was attached thereto prior to compact bonding for 5 minutes at 180° C. at a pressure of 30 Kg/cm². The combination was then heat treated for 60 minutes in a hot air oven at 180° C. to obtain a copper foil laminated film. The peel strength (T-peel, 25° C.) was measured to be 1.7 kgf/cm.

### COMPARATIVE EXAMPLE 1

A commercially available polyimide film (UPILEX 12.5S by Ube Industries, Ltd., 12.5 μm thickness) was used to fabricate a copper foil laminated film using an adhesive under the same conditions as above. The peel strength of this copper foil laminated film (T-peel, 25° C.) was measured to be about 0.25 kgf/cm.

### EXAMPLES 2 and 3

### Fabrication of Bilayer or Trilayer Polyimide Film

A bilayer and trilayer polyimide film with uniform surfaces and satisfactory transparency, having a surface-modifying polybenzimidazole layer thickness of 0.15 μm (Example 2) or 0.2 μm each (both sides) (Example 3), were obtained in the same manner as Example 1 except for changing the coating thickness of the surface-modifying polybenzimidazole solution (Example 2) or coating on both sides (Example 3). The bilayer and trilayer polyimide films had improved surface adhesion, as demonstrated below, while maintaining a low linear expansion coefficient, high elastic modulus and high strength as characteristics of the base polyimide film.

Rolled copper foil laminated films were fabricated: using an adhesive in the same manner as Example 1, except for using the bilayer and trilayer polyimide films, and the results were satisfactory. The peel strengths of the rolled copper foil laminated films using the adhesive (T-peel, 25° C.) were both 1.7 kgf/cm.

### EXAMPLE 4

### Fabrication of Bilayer Polyimide Film

A bilayer polyimide film with a uniform surface arid satisfactory transparency was obtained in the same manner as Example 1, except that the overall thickness of the bilayer polyimide film was changed for an overall bilayer polyimide film thickness of 25 μm. The bilayer polyimide film had improved surface adhesion, as demonstrated below, while maintaining a low linear expansion coefficient, high elastic modulus and high strength as characteristics of the base polyimide film.

A rolled copper foil laminated film using an adhesive was fabricated in the same manner as Example 1, except for using the bilayer polyimide film, and the results were satisfactory. The peel strength of the rolled copper foil laminated film using the adhesive (t-peel, 25° C.) was 1.7 kgf/cm.

### COMPARATIVE EXAMPLE 2

A copper foil laminate film using an adhesive was fabricated under the same conditions as above, using a commercially available polyimide film (UPILEX 25S by Ube Industries, Ltd., 25 μm thickness). The peel strength of the copper foil laminated film (T-peel, 25° C.) was measured to be about 0.5 kgf/cm.

The bilayer and trilayer polyimide films obtained in Examples 1 to 3 (thickness of 12.5 μm) exhibited a tensile modulus (MD) of 8.5 GPa, an elongation (MD) of 31%, a tensile strength (MD) of 420 MPa, a linear expansion coefficient (MD) (from 50 to 200° C.) of 13 ppm, a water absorption (in water at 23° C. for 24 hours) of 1.5%, a heat decomposition temperature (temperature at which 5% weight reduction occurred in air) of not lower than 590° C., and a surface resistance of 10¹⁶ Ω.

The bilayer polyimide film obtained in Example 4 (thickness of 25 μm) exhibited a tensile modulus (MD) of 7.5 GPa, an elongation (MD) of 30%, a tensile strength (MD) of 400 MPa, a linear expansion coefficient (MD) (from 50 to 200° C.) of 15 ppm, a water absorption (in water at 23° C. for 24 hours) of 1.5%, a heat decomposition temperature (temperature at which 5% weight reduction occurred in air) of not lower than 590° C., and a surface resistance of 10¹⁶ Ω.

A monolayer film fabricated in an analogous manner as in Example 1 by using only the surface-modifying polybenzimidazole solution and having a thickness of 40 μm exhibited a tensile modulus (MD) Of 4.5 GPa, an elongation (MD) of 30%, a tensile strength (MD) of 130 MPa, a linear expansion coefficient (MD) (from 50 to 200° C.) of 21 ppm, and a heat decomposition temperature (temperature at which 5% weight reduction occurred in air) of 580° C.

A monolayer film fabricated in an analogous manner as in Example 1 by using only the polyimide starting material dope and having a thickness of 12.5 μm exhibited a tensile modulus (MD) of 9.3 GPa, an elongation (MD) of 30%, a tensile strength (MD) of 460 MPa, a linear expansion coefficient (MD) (from 50 to 200°C.) of 10 ppm, a water absorption (in water at 23° C. for 24 hours) of 1.4%, a heat decomposition temperature (temperature at which 5% weight reduction occurred in air) of not lower than 590° C., and a surface resistance of not less than 10¹⁷ Ω.

A monolayer film fabricated in an analogous manner as in Example 1 by using only the polyimide starting material dope and having a thickness of 25 μm exhibited a tensile modulus (MD) of 8 GPa, an elongation (MD) of 36%, a tensile strength (MD) of 430 MPa, a linear expansion coefficient (MD) (from 50 to 200° C.) of 12 ppm, a water absorption (in water at 23° C. for 24hours) of 1.4%, a heat decomposition temperature (temperature at which 5% weight reduction occurred in air) of not lower than 590° C., and a surface, resistance of not less than 10¹⁷ Ω.

The above-described tensile modulus, elongation and tensile strength were measured in accordance with ASTM D882 method and the surface resistance was measured in accordance with ASTM D257 method.

### Fabrication of Copper-Clad Laminate by Sputtering

For formation of the metal layer, there were formed an approximately 0.5 μm nickel-chromium film and an approximately 0.4 μm copper film by sputtering, and an approximately 10 μm copper film was then formed by electroplating. The peel strength can be further improved, in necessary, by electrical treatment such as plasma treatment or corona treatment, or by physical or chemical treatment. The peel strength is defined as the value measured by the method described above with the laminate in a completely untreated state. This value accurately reflects the inherent peel strength of the polyimide film.

Specifically, the experiment was conducted under the following conditions:

Reverse sputtering conditions (initiated at less than 2 × 10⁻⁴ Pa)

| | | |
|---|---|---|
| Ar gas pressure: | 2 | mTorr |
| Ar gas flow rate: | 50 | sccm |
| RF power: | 100 | W |
| Time: | 30 | sec |

Sputtering conditions

| | | |
|---|---|---|
| Ar gas pressure: | 3.7 | mTorr |
| Ar gas flow rate: | 50 | sccm |
| DC power: | 150 | W |

| | |
|---|---|
| NiCr film-forming time: | 5 sec (50 Å) |
| Cu film-forming time: | 4 min, 4.0 sec (4000 Å) |

The base temperature was room temperature (cooled water flow).

### EXAMPLE 5

A bilayer polyimide film (total thickness: 12.5 μm) was fabricated having a polybenzimidazole layer (approximately 0.2 μm) covered (laminated) on the surface in the same manner as Example 1. A sputtering method was used to form an approximately 0.5 μm nickel-chromium film and an approximately 0.4 μm copper film thereover and electroplating was used to form an approximately 10 μm copper film; the peel strength (T-peel, 25° C.) was measured to be approximately 0.5 kgf/cm.

### EXAMPLE 6

A bilayer polyimide film (total thickness: 35 μm) was fabricated having a polybenzimidazole layer (approximately 0.2 μm) covered (laminated) on the surface in the same mariner as Example 1. A sputtering method was used to form an approximately 0.5 μm nickel-chromium film and an approximately 0.4 μm copper film thereover and electroplating was used to form an approximately 10 μm copper film; the peel strength (T-peel, 25° C.) was measured to be approximately 0.6 kgf/cm.

### COMPARATIVE EXAMPLE 3

An approximately 0.5 μm nickel-chromium film and art approximately 0.4 μm copper film were formed by sputtering and an approximately 10 μm copper film was formed thereover by electroplating, using a commercially available polyimide film (UPILEX 12.5SN by Ube Industries, Ltd., 12.5 μm thickness); the peel strength (T-peel, 25° C.) was measured to be about 0.2 kgf/cm.

### COMPARATIVE EXAMPLE 4

An approximately 0.5 μm nickel-chromium film and an approximately 0.4 μm copper film were formed by sputtering and an approximately 10 μm copper film was formed thereover by electroplating, using a commercially available polyimide film (UPILEX 25S by Ube Industries, Ltd., 25 μm thickness); the peel strength (T-peel, 25° C.) was measured to be about 0.25 kgf/cm.

1. A laminated body obtained by forming a metal-deposited layer onto one or both adhesion-improved sides of a polyimide film with improved adhesion obtained by coating and spraying an organic polar solvent solution containing a polybenzimidazole onto one or both sides of a self-supporting film prepared by casting and drying a dope, which is an organic polar solvent solution of a polyimide precursor which may contain an imidization catalyst, onto a support and then heat treating the film to form a multilayer polyimide film of a base polyimide layer and one or two polybenzimidazole layers, by vapor deposition or sputtering, and then plating with metal to form a metal layer onto the metal-deposited layer.

2. The laminated body according to claim 1, wherein the thickness of the polybenzimidazole layer is 0.01-3.0 μm.

3. The laminated body according to claim 1, wherein the polyimide precursor is produced from 3,3′,4,4′-biphenyltetracarboxylic dianhydride (s-BPDA), para-phenylenediamine (PPD) and 4,4′-diaminodiphenylether (DADE) and has a PPD/DADE molar ratio between 100/0 and 85/15, is produced from s-BPDA, pyromellitic dianhydride, PPD and DADE and has a PPD/DADE molar ratio between 90/10 and 10/90, is produced from pyromellitic dianhydride, PPD and DADE and has a PPD/DADE molar ratio between 90/10 and 10/90, or is produced from 3,3′,4,4′-benzophenonetetracarboxylic dianhydride (BTDA), pyromellitic dianhydride, PPD and DADE and has a PPD/DADE molar ratio between 20/80 and 90/10 in the acid dianhydride and a PPD/DADE molar ratio between 30/70 and 90/10 in the diamine.

4. The laminated body according to claim 1, wherein tile thickness of the metal-deposited film obtained by sputtering is between 10 nm and 1 μm.

5. The laminated body according to claim 1, wherein the metal-deposited film has a structure with two or more layers comprising an underlying layer and a surface deposited metal layer, the underlying layer being composed of one member selected from chromium, titanium, palladium, zinc, molybdenum, nickel, cobalt, zirconium arid iron and the surface deposited metal layer being composed of copper.

6. The laminated body according to claim 1, wherein the material for the metal plating layer formed on the metal-deposited layer is copper, copper alloy or silver.

7. The laminated body according to claim 1, wherein the metal plating layer is formed by an electroless plating or electroplating method.

8. The laminated body according to claim 1, wherein the organic polar solvent solution of a polyimide precursor has a polymer concentration of 8-25 wt % and is heated at 100-180° C. for 5-60 minutes to prepare the self-supporting film.

9. The laminated body according to claim 1, wherein the organic polar solvent solution containing a polybenzimidazole has a polymer concentration of 0.1-10 wt %.

10. The laminated body according to claim 1, wherein the self-supporting film onto which the organic polar solvent solution containing a polybenzimidazole has been coated or sprayed is heat treated at a temperature above the glass transition temperature Of the polyimide arid no higher than 500° C.

11. The laminated body according to claim 1, wherein the base polyimide layer has a thickness of 10-100 μm, the multilayer polyimide film has a tensile strength of 30-100 kg/mm², an elastic modulus of 600-1200 kg/mm², an elongation of 30-100%, a water absorption (after 24 hours immersed in water at 23° C.) of no greater than 1.5% and a thermal expansion coefficient (23-300° C., both TD and MD) of 0.5-2.5×10⁻⁵ cm/cm/° C.

12. A process for producing a laminated body whereby a metal-deposited layer is formed onto one or both adhesion-improved sides of a polyimide film with improved adhesion obtained by coating and spraying an organic polar solvent solution containing a polybenzimidazole onto one or both sides of a self-supporting film prepared by casting and drying a dope, which is an organic polar solvent solution of a polyimide precursor which may contain an imidization catalyst, onto a support and then heat treating the film to form a multilayer polyimide film of a base polyimide layer and one or two polybenzimidazole layers, by vapor deposition or sputtering, and then metal is plated to form a metal layer onto the metal-deposited layer.
